(19) United States
(12) Patent Application Publication
(10) Pub. No.: US 2014/0103190 A1
(43) Pub. Date: Apr. 17, 2014

(54) BINARY IMAGE SENSOR AND IMAGE SENSING METHOD

(71) Applicant: SAMSUNG ELECTRONICS CO., LTD., SUWON-SI (KR)

(72) Inventors: KWANGHYUN LEE, SEONGNAM-SI (KR); TAECHAN KIM, YONGIN-SI (KR); TAEYON LEE, SEOUL (KR); YOUNGGU JIN, OSAN-SI (KR)

(73) Assignee: SAMSUNG ELECTRONICS CO., LTD., SUWON-SI (KR)

(21) Appl. No.: 14/026,388

(22) Filed: Sep. 13, 2013

Related U.S. Application Data
(60) Provisional application No. 61/713,175, filed on Oct. 12, 2012.

(30) Foreign Application Priority Data
Mar. 7, 2013 (KR) 10-2013-0024617

(51) Int. Cl. H01L 27/146

(52) U.S. Cl. CPC H01L 27/14612
USPC 250/208.1

(57) ABSTRACT

A binary image sensor includes; binary pixels, each having a transistor structure, being coupled between a drain line and a column line and generating a number of photons in response to incident light, sense amplifiers connected to a respective column line and outputting a binary value in response to detecting a voltage corresponding to current flowing to the column line when a gate voltage is applied to a gate line connected to a gate of a binary pixel, and an accumulator configured to accumulate binary values output by the sense amplifiers.

### CROSS-REFERENCE TO RELATED APPLICATIONS

This non-provisional U.S. patent application claims priority under 35 USC §119 to provisional U.S. Patent Application No. 61/713,175 filed Oct. 12, 2012, and to Korean Patent Application No. 10-2013-0024617 filed on Mar. 7, 2013, the collective subject matter is hereby incorporated by reference.

### BACKGROUND

Embodiments of inventive concept relates to binary image sensors and related image sensing methods.

A Charge-Couple Device (CCD) image sensor or Complementary Metal Oxide Semiconductor (CMOS) image sensor typically includes an array of pixels. Each pixel has a size of approximately 2 micrometers. It is conventionally possible to fabricate pixels having a size less than 2 micrometers. However, it is difficult to obtain performance improvements for image sensors including pixels having a size less than 1 micrometer. This performance limitation is due to the very narrow dynamic range, small well capacity, and/or reduced signal to noise ratio (SNR) of such image sensors.

Conversion gain—a measure of efficiency in the conversion of charge to voltage—is related to capacitance of the light receiving region. The higher the capacitance of the light receiving region, the smaller the conversion gain. The smaller the size of a device, the higher relative capacitance. Therefore, the conversion gain is significantly reduced. There is a need for processing a signal using a structure and approach that are different from those used by conventional image sensors in order to effectively reduce the size of constituent pixels. In keeping with the need, a number of studies have recently focused on the design and fabrication of binary image sensors. One study that may be usefully referenced as background to the subject inventive concept is, Fossum, Eric, “Quanta Image Sensor: Possible Paradigm Shift for the Future,” IntertechPira Image Sensors (Mar. 22, 2012) London, England, U.K.

### SUMMARY

In certain embodiments of the inventive concept, a binary image sensor includes; binary pixels arranged in a matrix, each binary pixel having a transistor structure, being respectively coupled between a drain line and column line among a plurality of drain lines and column lines in the matrix, and generating a number of photons in response to incident light, sense amplifiers, each sense amplifier being connected to a column line and configured to output a binary value in response to detecting a voltage corresponding to current flowing to the column line when a gate voltage is applied to a gate line connected to a gate of a binary pixel, and an accumulator configured to accumulate binary values output by the sense amplifiers.

In certain embodiments of the inventive concept, a method of sensing image data using an array of pixels respectively formed by a plurality of binary pixels arranged in a matrix includes; determining and storing a number of ON binary pixels for each respective pixel, and outputting image data for each respective pixel corresponding to the stored number of ON binary pixels. The determining and storing the number of ON binary pixels includes for each one of the plurality binary pixels, sensing a voltage corresponding to a current flowing through a channel of the binary pixel, and outputting a binary value in response to the sensed voltage.

In certain embodiments of the inventive concept, a method of operating a binary image sensor, wherein the binary image sensor includes a pixel formed by a plurality of binary pixels having a transistor structure and being coupled between a drain line and column line, includes; receiving incident light upon the binary pixel, and generating a number of photons in response to the incident light, applying a low gate voltage to a gate of the binary pixel, while the low gate voltage is applied to the gate of the binary pixel, sensing a voltage apparent on the column line and corresponding to a number of photons generated in response to the incident light, outputting a binary value in response to the sensed voltage, and accumulating the binary value.

### BRIEF DESCRIPTION OF THE DRAWINGS

FIG. 1 is a diagram that illustrates a pixel layout structure according to an embodiment of the inventive concept.

FIG. 2A is a cross-sectional diagram illustrating a binary pixel having a transistor structure according to one embodiment of the inventive concept.

FIG. 2B is a cross-sectional diagram illustrating a binary pixel having a transistor structure according to another embodiment of the inventive concept.

FIG. 2C is a cross-sectional diagram illustrating a binary pixel having a transistor structure according to still another embodiment of the inventive concept.

FIG. 3 is a block diagram illustrating an image sensor according to an embodiment of the inventive concept.

FIG. 4 is a conceptual diagram illustrating the operation of the image sensor of FIG. 3.

FIG. 5 is a partial circuit diagram illustrating a sense amplifier that may be used in a sense amplifier circuit of an embodiment of the inventive concept.

FIG. 6 is a timing diagram illustrating the operation of the sense amplifier of FIG. 5.

FIG. 7 is a general flowchart summarizing one possible method of operating a binary image sensor according to certain embodiments of the inventive concept.

FIG. 8 is a general block diagram of an electronic device that may incorporate an image sensor according to certain embodiments of the inventive concept.

### DETAILED DESCRIPTION

Embodiments of the inventive concept will now be described is some additional detail with reference to the accompanying drawings. The inventive concept may, however, be variously embodied in different forms and should not be construed as being limited to only the illustrated embodiments. Rather, these embodiments are provided so that this description will be thorough and complete, and will fully convey the making and use of the inventive concept to those of ordinary skill in the art. Throughout the written description and drawings, like reference numbers and labels are used to denote like or similar elements. In the drawings, size, thickness(es) and relative thickness(es) of certain layers and regions may be exaggerated for clarity.

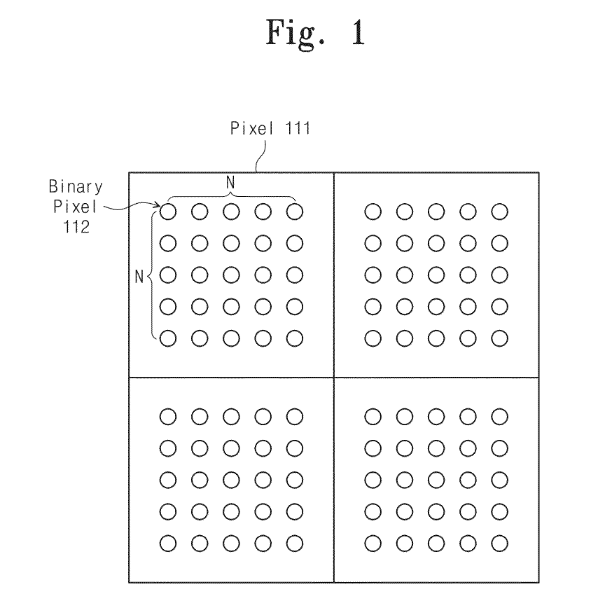

FIG. 1 is a diagram illustrating one possible pixel structure for an embodiment of the inventive concept. Referring to FIG. 1, a unit pixel or “pixel” 111 includes a plurality of sub-pixels pixels, hereafter individually referred to as a “binary pixel” 112. The plurality of binary pixels 112 is arranged in an N×N array, wherein “N” is an integer greater than 1. Each pixel 111 may be a red pixel, a green pixel, a blue pixel, a white pixel or a black pixel.

In certain embodiments of the inventive concept, a color filter may be formed on each pixel 111 to selectively transmit light in a wavelength to be detected (e.g., red, green, blue). In other embodiments of the inventive concept, a color filter may be formed on each binary pixel 112 to selectively transmit light in a wavelength to be detected. Additionally, a micro-lens (or condensing lens) may be mounted on a color filter.

In certain embodiments of the inventive concept, each pixel 111 may include binary pixels of the same color, while in other embodiments each the pixel 111 may include binary pixels having two or more colors.

Regardless of specific configuration, each binary pixel 112 may be used to develop and store “binary information” that is correlated with a number of incident photons upon the binary pixel 112 relative to at least one threshold. Hence, when the number of incident photons to a binary pixel 112 exceeds a given threshold value, its binary information (i.e., image data) may be defined as a digital binary value of “1”. In contrast, when the number of incident photons to the binary pixel 112 is less than the threshold value, the binary information indicates may be defined as “0”.

Given this configuration, each pixel 111, including a plurality of binary pixels, wherein each binary pixel provides a binary value over a defined time period in response to incident light, may provide “pixel image data” that is determined by summing a plurality of “sub-pixel binary values” provided by the constituent plurality of binary pixels.

In certain embodiments of the inventive concept, each binary pixel 112 may be implemented with a transistor structure. However, this need not always be the case.

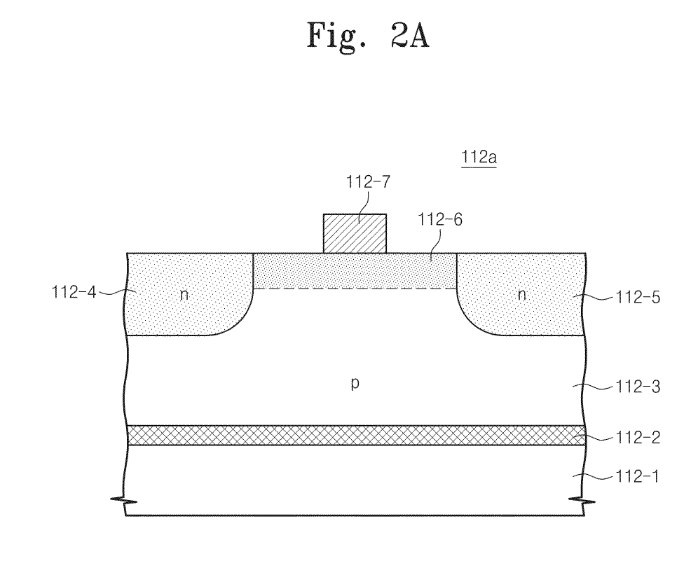

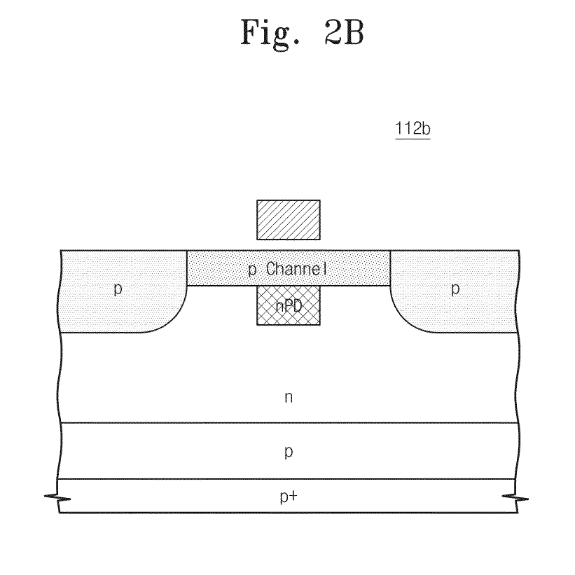

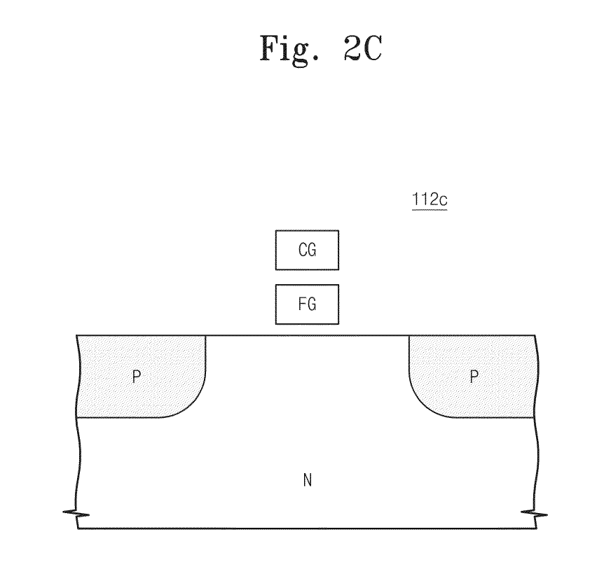

FIG. 2A illustrates a binary pixel 112a having a transistor structure according to one embodiment of the inventive concept. Referring to FIG. 2A, the binary pixel 112a includes a floating body transistor. That is, the binary pixel 112a includes an insulating layer 112-2 on a back gate 112-1 and a semiconductor layer 112-3 on the insulating layer 112-1. The back gate 112-1 may be a silicon layer and the insulating layer 112-2 may be a silicon oxide layer acting as a gate insulating layer. The semiconductor layer 112-3 may be a P-type silicon layer. Under this assumption of substrate type, a source region 112-4 and a drain region 112-5 may be selectively formed by doping N-type impurities in the silicon layer 112-3. The space between the source region 112-4 and drain region 112-5 in the silicon layer 112-3 may be termed a floating body region 112-6.

A metal nano-dot may be disposed on the surface of the floating body region 112-6. The metal nano-dot 112-7 may be made of one of metals such as Ag, Au, Al, Pt, Ni, Ti, and Cu. When light is incident upon the floating body region 112-6 (i.e., as focused by a micro-lens and a color filter, not shown), the light is scattered by the metal nano-dot 112-7, and a near field is formed while free electrons of the metal nano-dot 112-7 oscillate in response to the scattered light. In this manner, light may be concentrated around the metal nano-dot 112-7. As a result, the metal nano-dot 112-7 has the effect of secondarily focusing the incident light.

The binary pixel 112a shown in FIG. 2A has an N-type MOS (NMOS) transistor structure. However, embodiments of the inventive concept are not limited to NMOS transistor structures, but may be implemented with a P-type MOS (PMOS) transistor structures.

FIG. 2B illustrates a binary pixel 112b having a transistor structure according to another embodiment of the inventive concept. Referring to FIG. 2B, the binary pixel 112b is implemented with a PMOS transistor structure, but the PMOS transistor structure is similar to that of a flash memory cell, as will be appreciated by those skilled in the art.

FIG. 2C illustrates a binary pixel 112c having a transistor structure according to still another embodiment of the inventive concept. Referring to FIG. 2C, the binary pixel 112c is implemented with a transistor structure of a NAND/NOR flash memory cell. In this regard, the binary pixel 112c includes a control gate (CG), a floating gate (FG), and a N-type substrate including source and drain regions. A material is provided between the source and drain regions to cause photons to be generated in response to incident light.

A threshold voltage of the binary pixel 112c may be controlled by the amount of charge trapped by the floating gate (FG). When the number of photons generated by the incident light overcomes the threshold voltage of the binary pixel 112c, the source and drain regions will become electrically connected to each other (i.e., the binary pixel 112c may be turned ON). In contrast, when the number of photons generated by the incident light does not overcome the threshold voltage of the binary pixel 112c, the source and drain regions remain electrically isolated from each other (i.e., the binary pixel 112c remains turned OFF). For convenience of description, it is assumed hereafter that each binary pixel 112 is implemented with a flash memory cell structure.

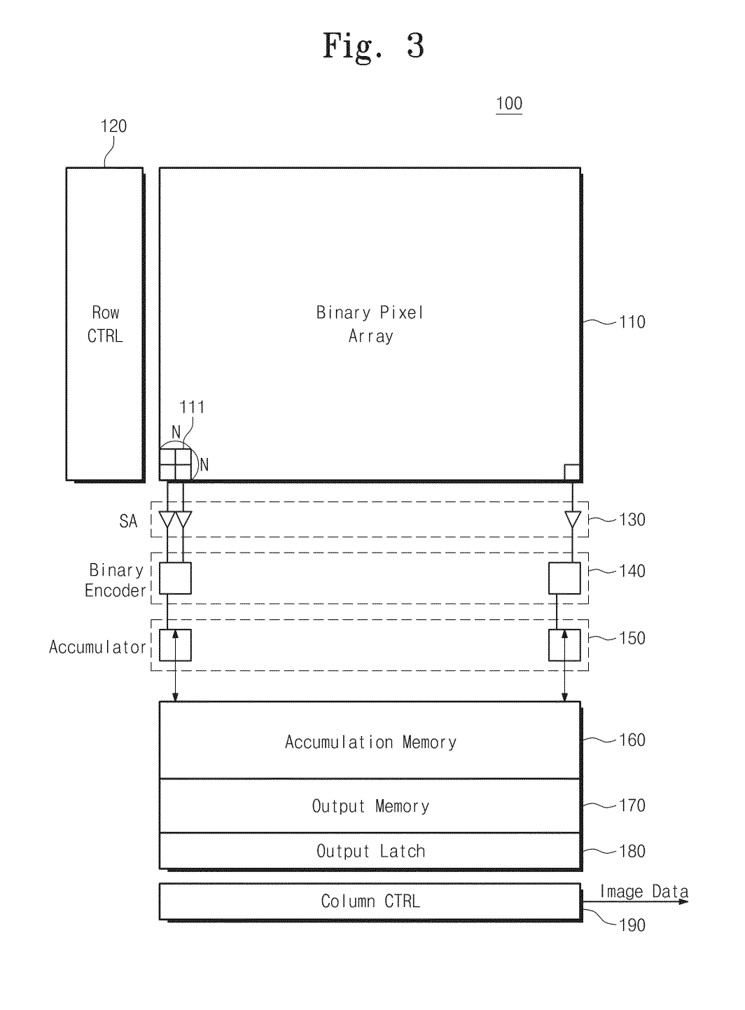

FIG. 3 is a block diagram illustrating an image sensor 100 according to an embodiment of the inventive concept. Referring to FIG. 3, the image sensor 100 includes a binary pixel array 110, a row controller 120, a sense amplifier circuit 130, a binary encoder 140, an accumulator 150, an accumulator memory 160, an output memory 170, an output latch 180, and a column controller 190.

The binary pixel array 110 includes binary pixels (or “JOT”) 111 formed in a N×N matrix at the respective intersections of row lines and column lines that may correspond to one pixel of a final image.

The row controller 120 controls row lines to obtain image data. The sense amplifier circuit 130 includes a plurality of sense amplifiers to determine whether photons exceeding a threshold value are received by a binary pixel connected to a single row line and a single column line. The binary encoder 140 then sequentially converts in a row line-by-row line, or column line-by-column line manner a number “ON binary pixels” receiving a number of photons exceeding the threshold value into a corresponding binary number.

The accumulator 150 accumulates the binary number converted by the binary encoder 140 by selecting N row lines. The accumulator memory 160 adds previously stored binary number and the accumulated binary number, and stores the added binary number when the accumulation of the binary number to the N row lines is ended. When the binary number storing operation according to predetermined binary planes (or “frames”) is ended, the output memory 170 receives the stored binary number from the accumulator memory 160. The output latch 180 latches stored values from the output memory 170. The column controller 190 sequentially outputs the values stored in the output latch 180. In this manner, sensed image data may be output.

Thus, the binary image sensor 100 according to certain embodiments of the inventive concept may accumulate and store a number of turned-ON or simply, ON binary pixels.

The binary image sensor 100 illustrated in FIG. 3 has a structure to accumulate and store binary values of binary pixels constituting a single pixel. However, the inventive concept is not limited thereto. A binary image sensor according to an embodiment of the inventive concept may be implemented with a structure to count binary values of binary pixels in various manners.

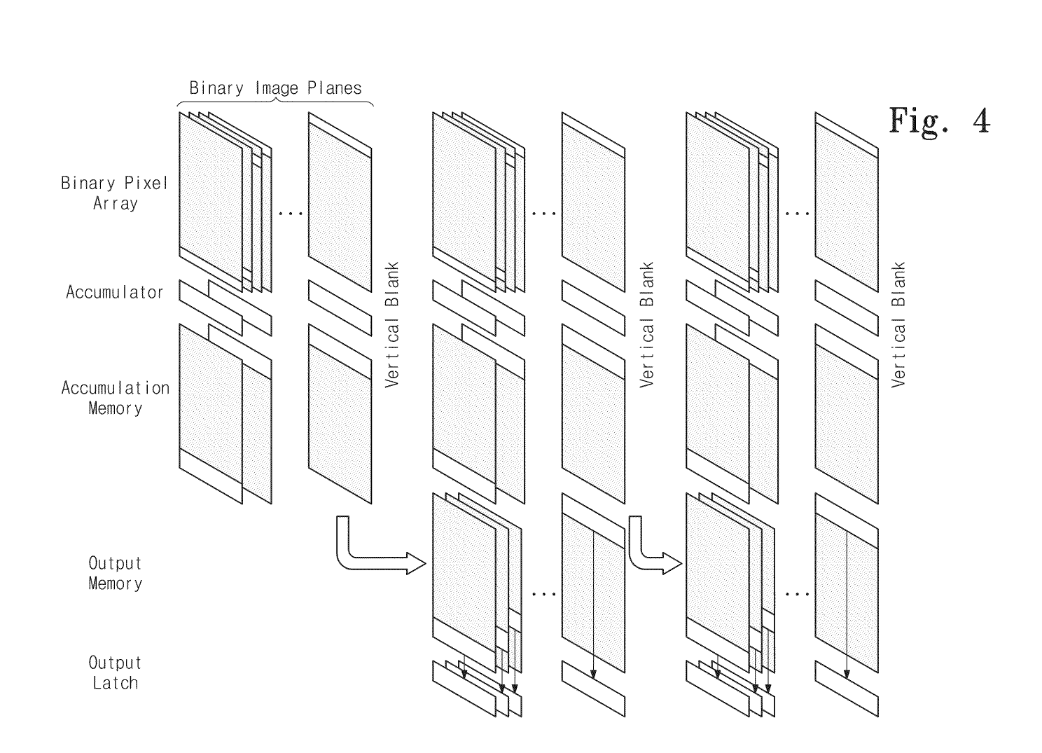

FIG. 4 is a conceptual diagram illustrating the operation of the image sensor 100 in FIG. 3. Referring to FIG. 4, after binary numbers for a plurality of binary image planes (i.e., individual frames) are stored, said binary numbers may be transmitted to an output memory (170 in FIG. 3). Then, values stored in the output memory may be sequentially output for each frame. In this manner, an output memory may be used to spatially or temporally store image data from a number of binary image planes.

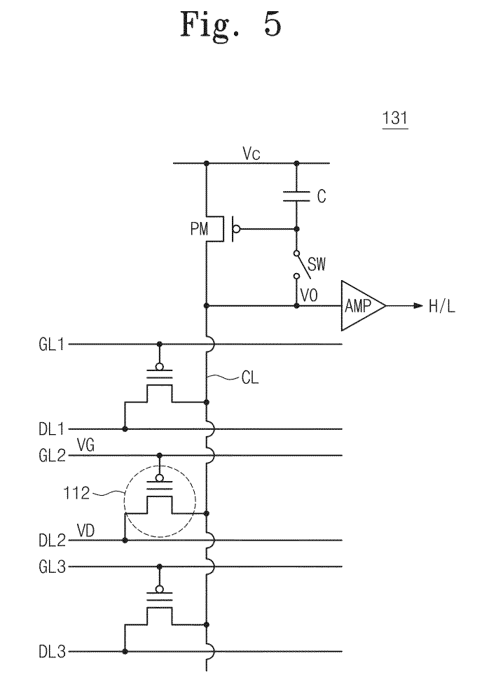

FIG. 5 illustrates a sense amplifier (SA) 131 that may be used in the sense amplifier circuit 130 of FIG. 3 according to certain embodiments of the inventive concept. Referring to FIG. 5, the sense amplifier 131 includes a PMOS transistor (PM), a capacitor (C), a switch (SW), and an amplifier (AMP). The PMOS transistor is coupled between a terminal of a constant voltage (Vc) and a column line (CL). In the illustrated embodiment of FIG. 5, the constant voltage Vc may be a power supply voltage. The capacitor is connected between the constant voltage Vc and the gate of the PMOS transistor. The amplifier receives and amplifies a drain voltage (VO) of the PMOS transistor.

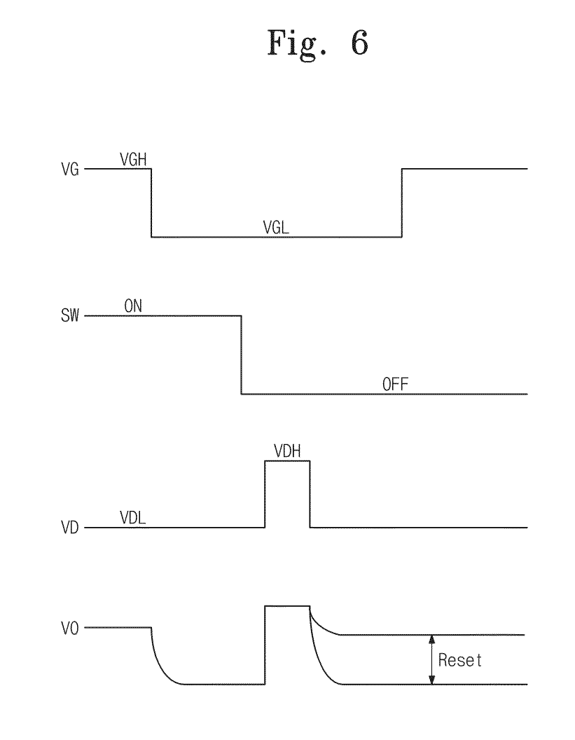

The sense amplifier 131 of FIG. 5 may be used to detect a current flowing to the column line in order to detect a binary value of a corresponding binary pixel 112. This approach will be further described in the context of FIG. 6.

FIG. 6 is a timing diagram illustrating the operation of the sense amplifier 131 of FIG. 5. Binary pixels (e.g., 112) are assumed to be coupled between respective drain lines (DL1˜DL3) as shown in FIG. 5. The gate lines (GL1˜GL3) are connected to the respective gates of the binary pixels. In the illustrated embodiment of FIG. 5, the drain lines (DL1˜DL3) are commonly connected to the column line (CL). In terms of functionality, the gate lines (GL1˜GL3) may be referred to as “sense lines” adapted to transfer a “sensing voltage” developed during a sensing operation for the respective binary pixels. The drain lines (DL1-DL3) may be referred to as “reset lines” adapted to transfer a reset voltage during a reset operation for the respective binary pixels.

Referring to FIGS. 5 and 6, the operation of the sense amplifier 131 will now be described in some additional detail. When a “low” gate voltage (VG) is applied to a selected gate line, the corresponding binary pixel 112 may be turned ON. When the switch is open, a drain voltage of the PMOS transistor will be formed such that current equal to the amount of current flowing to a channel of the binary pixel 112 flows to the column line. The gate voltage may be stored in the capacitor. Then, when the switch is closed, an amplified version (H/L) of the drain voltage is provide by the amplifier.

The drain voltage (VD) apparent to each of the drain lines may be used to remove photons generated at the binary pixel 112. That is, a “high” drain voltage (HDL) may be used to remove photons. A default value for the drain voltage may thus be established as (VDL).

When there are no photons incident upon the binary pixel 112, the threshold voltage of the binary pixel 112 will not change, but as photon(s) are received by the binary pixel 112, the threshold voltage of the binary pixel 112 will change. Hence, the output voltage (VO) will also change in accordance with the change in the threshold voltage.

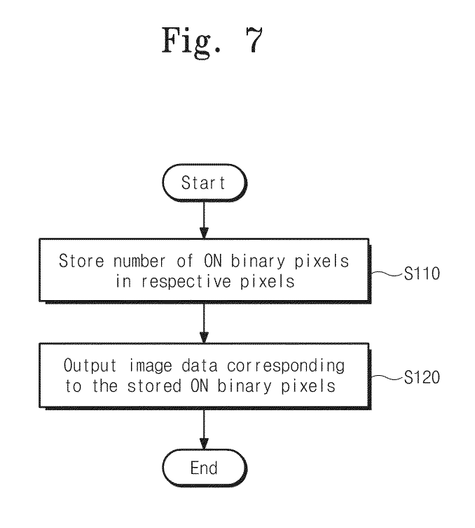

FIG. 7 is a general flowchart summarizing a method of sensing image data for a binary image sensor according to embodiments of the inventive concept. Referring collectively to FIGS. 1, 3, 4, 5, 6 and 7, the image sensing method will now be described. For convenience of description, it is assumed that a single pixel includes an N×N plurality of binary pixels, as shown in FIG. 1. The number of ON binary pixels among the respective pixels may be stored (S110). The number of ON binary pixels corresponding to each of the pixels may be determined by detecting a voltage corresponding to a current flowing to a channel of a binary pixel, outputting a binary value based on the detected voltage, accumulating the output binary value, and storing the accumulated binary value, as shown in FIG. 3. Image data corresponding to the number of the stored binary pixels may be output (S120). In an exemplary embodiment of the inventive concept, binary voltage corresponding to frame information may be stored in an output memory, and the N×N plurality of binary pixels may be reset to sense the next image data after the current image data has been output.

According to the above-described image sensing method, image data may be output based on a number of ON binary pixels.

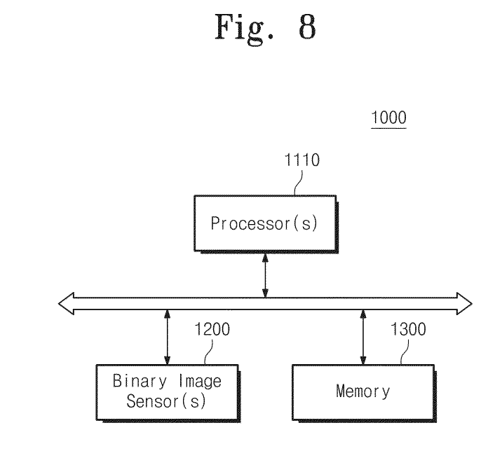

FIG. 8 is a block diagram generally illustrating an electronic device 1000 according to certain embodiments of the inventive concept. Referring to FIG. 8, the electronic device 1000 includes at least one processor 1100, at least one binary image sensor 1200, and a memory 1300. The at least one binary image sensor 1200 may be implemented with the same configuration or method as the binary image sensor 100 illustrated in FIG. 3.

As described above, a binary image sensor according to embodiments of the inventive concept may be used to output image data corresponding to a number of ON binary pixels assuming a pixel of reduced size. Nonetheless, enhance performance may be obtained for the pixel.

While the inventive concept have been particularly shown and described with reference to embodiments thereof, it will be apparent to those of ordinary skill in the art that various changes in form and detail may be made therein without departing from the scope of the inventive concept as defined by the following claims.

What is claimed is:

1. A binary image sensor comprising:
binary pixels arranged in a matrix, each binary pixel having a transistor structure, being respectively coupled between a drain line and column line among a plurality of drain lines and column lines in the matrix, and generating a number of photons in response to incident light;
sense amplifiers, each sense amplifier being connected to a column line and configured to output a binary value in response to detecting a voltage corresponding to current flowing to the column line when a gate voltage is applied to a gate line connected to a gate of a binary pixel; and
an accumulator configured to accumulate binary values output by the sense amplifiers.

2. The binary image sensor of claim 1, wherein each of the binary pixels has a N-type Metal Oxide Semiconductor (NMOS) transistor structure.

3. The binary image sensor of claim 1, wherein each of the binary pixels has a P-type Metal Oxide Semiconductor (PMOS) transistor structure.

4. The binary image sensor of claim 1, wherein each of the binary pixels has a flash memory cell structure.

5. The binary image sensor of claim 1, wherein for binary pixels commonly connected to a gate line, a set of the binary pixels commonly connected to the gate line that generates photons exceeding a threshold value are turned ON when a low gate voltage is respectively applied to the set of binary pixels.

6. The binary image sensor of claim 1, wherein the binary pixels are reset by applying a high drain voltage to the drain lines.

7. The binary image sensor of claim 1, wherein each sense amplifier comprises:
a PMOS transistor coupled between a constant voltage and a column line;
a switch coupled between the column line and a gate of the PMOS transistor;
a capacitor coupled between the constant voltage and the gate of the PMOS transistor; and
an amplifier configured to receive and amplify a drain voltage of the PMOS transistor.

8. The binary image sensor of claim 1, further comprising:
an accumulator memory configured to store the accumulated values in the accumulator.

9. The binary image sensor of claim 8, further comprising:
a binary encoder configured to encode values output from the sense amplifiers as binary values.

10. The binary image sensor of claim 1, further comprising:
an output memory configured to receive stored values from the accumulator for the stored values corresponding to frame information.

11. The binary image sensor of claim 10, further comprising:
a latch configured to latch image data output from the output memory.

12. A method of sensing image data using an array of pixels respectively formed by a plurality of binary pixels arranged in a matrix, the method comprising:
determining and storing a number of ON binary pixels for each respective pixel; and
outputting image data for each respective pixel corresponding to the stored number of ON binary pixels,
wherein determining and storing the number of ON binary pixels comprises for each one of the plurality binary pixels:
sensing a voltage corresponding to a current flowing through a channel of the binary pixel; and
outputting a binary value in response to the sensed voltage.

13. The method of claim 12, further comprising:
accumulating the binary value as output in response to the sensed voltage; and
storing the accumulated binary value.

14. The method of claim 12, further comprising:
storing binary values corresponding to frame information in an output memory.

15. The method of claim 12, further comprising:
resetting the plurality of binary pixels after outputting the image data.

16. A method of operating a binary image sensor, wherein the binary image sensor includes a pixel formed by a plurality of binary pixels having a transistor structure and being coupled between a drain line and column line, the method comprising:
receiving incident light upon the binary pixel, and generating a number of photons in response to the incident light;
applying a low gate voltage to a gate of the binary pixel;
while the low gate voltage is applied to the gate of the binary pixel, sensing a voltage apparent on the column line and corresponding to a number of photons generated in response to the incident light;
outputting a binary value in response to the sensed voltage; and
accumulating the binary value.

17. The method of claim 16, wherein each of the binary pixels has one of a N-type Metal Oxide Semiconductor (NMOS) transistor structure, and a P-type Metal Oxide Semiconductor (PMOS) transistor structure.

18. The method of claim 16, wherein the pixel is one of a red pixel, a green pixel and a blue pixel.

19. The method of claim 18, wherein each one of the plurality of binary pixels is a red binary pixel, a green binary pixel and a blue binary pixel.

20. The method of claim 16, further comprising:
applying a high drain voltage to the drain line to reset the pixel.
